(19) United States
(12) Patent Application Publication
(10) Pub. No.: US 2019/0280134 A1
(43) Pub. Date: Sep. 12, 2019

(54) CONFINED CONTACT AREA ON A SILICON WAFER

(71) Applicant: Heraeus Precious Metals North America Conshohocken LLC, West Conshohocken, PA (US)

(72) Inventors: Li Yan, Warrington, PA (US); Vinodh Chandrasekaran, Malvern, PA (US); Lei Wang, Berwyn, PA (US); Chi Long Chen, Singapore (SG); Lin Jiang, Media, PA (US); Cuiwen Guo, North Wales, PA (US); Weiming Zhang, Blue Bell, PA (US); Jing (Crystal) Han, Lafayette, PA (US)

(21) Appl. No.: 15/928,519

(22) Filed: Mar. 22, 2018

Related U.S. Application Data
(60) Provisional application No. 62/640,757, filed on Mar. 9, 2018.

(51) Int. Cl. H01L 31/0224; H01L 31/18; H01B 1/22; C03C 8/18; C03C 4/14

(52) U.S. Cl. CPC H01L 31/022425; H01L 31/1864; H01B 1/22; C03C 2207/00; C03C 4/14; C03C 2204/00; C03C 8/18

(57) ABSTRACT

The invention provides a method of preparing a metallization structure on a solar cell. The method includes patterning a first composition on a surface of a semiconductor substrate; and applying a second composition over the first composition. An area covered by the first composition is 5-95% of an area covered by the second composition. The semiconductor substrate is then subjected to firing conditions. The invention also provides a metallization structure formed using the method described herein.

### TECHNICAL FIELD

The invention provides a method for preparing a metallization structure on a solar cell. The method comprises: 1) patterning a first composition on a surface of a semiconductor substrate; and 2) applying a second composition over the first composition. The second composition covers a much larger area than the first composition, wherein an area of the first composition is 5-95% of an area of the second composition. Upon firing of the silicon wafer, the first composition forms a conductive contact layer, and the second composition forms an electroconductive layer.

### BACKGROUND

Solar cells are generally made of semiconductor materials, such as silicon (Si), which convert sunlight into useful electrical energy. The production of a silicon solar cell typically starts with a p-type silicon substrate in the form of a silicon wafer on which an n-type diffusion layer of the reverse conductivity type is formed by the thermal diffusion of phosphorus (P) or the like. Phosphorus oxychloride (POCl₃) is commonly used as the gaseous phosphorus diffusion source, other liquid sources are phosphoric acid and the like. In the absence of any particular modification, the diffusion layer is formed over the entire surface of the silicon substrate. The p-n junction is formed where the concentration of the p-type dopant equals the concentration of the n-type dopant; conventional cells that have the p-n junction close to the illuminated side, have a junction depth between 0.05 and 0.5 μm.

After formation of this diffusion layer excess surface glass is removed from the rest of the surfaces by etching by an acid such as hydrofluoric acid. Next, an ARC layer (aka antireflective coating layer) of Al₂O₃, TiOₓ, SiOₓ, TiOₓ/SiOₓ, or, in particular, SiNₓ or Si₃N₄ is formed on the n-type diffusion layer to a thickness of between 0.05 and 0.1 μm by a process, such as, for example, plasma CVD (chemical vapor deposition). One or more passivation layers may be applied to the front and/or back side of the silicon wafer as an outer layer. The passivation layer(s) may be applied before the front electrode is formed, or before the antireflective layer is applied (if one is present). Preferred passivation layers are those which reduce the rate of electron/hole recombination in the vicinity of the electrode interface. Preferred passivation layers include, but are not limited to, silicon nitride, silicon dioxide and titanium dioxide.

A conventional solar cell structure with a p-type base typically has a negative grid electrode on the front-side of the cell and a positive electrode on the back-side. The grid electrode is typically applied by screen printing and drying a front-side silver paste (front electrode forming silver paste) on the ARC layer on the front-side of the cell. The front-side grid electrode is typically screen printed. These two dimensional electrode grid pattern known as a front contact makes a connection to the p-type emitter of silicon. In addition, a back-side silver paste and an aluminum paste are screen printed (or some other application method) and successively dried on the back-side of the substrate. Normally, the back-side silver paste is screen printed onto the silicon wafer's back-side first as four or five parallel busbars or as rectangles (tabs) ready for soldering interconnection strings (presoldered copper ribbons). The aluminum paste is then printed in the bare areas with a slight overlap over the back-side silver. In some cases, the silver paste is printed after the aluminum paste has been printed. Firing is then typically carried out in a belt furnace for a period of 1 to 5 minutes with the wafer reaching a peak temperature in the range of 700 to 900° C. The front grid electrode and the back electrodes can be fired sequentially or cofired.

When the wafer is fired, the organic vehicle decomposes and the glass frit softens and then dissolves the passivation and/or the ARC layer and creating a pathway for the silver in the paste to reach silicon by forming a multitude of random points under the finger line or busbar patterns formed by the paste. These damaged SiNₓ passivation layer areas allow contact of silver crystallites in the silver paste with the underlying p-type silicon wafer and allow electric charge carriers to tunnel to the bulk silver. The undesired recombination of electrical charge causes a reduced Voc of the solar cell. If etching or damage of the passivation layer can be controlled or limited, then metal-silicon contact can be minimized. The preservation of the passivation layer may lead to a higher Voc which in turn improve the solar cell efficiency.

The printing involved in solar cell fabrication is directed to providing contact between the electron-generating wafer and the conductive finger lines and busbars so that the electrical charge is collected, and providing conductance in the finger lines and busbars so that the collected electrical charge is lead away by the gridlines. The first step requires opening a contact through the surface passivation or ARC layer. In general small contact openings and fine distribution of the openings on the wafer limit the undesired recombination of electrical charge but may increase resistive losses due to increased distances electrical carriers must travel in the relatively poorly conductive semiconductor wafer in order to reach the highly conductive grid lines. To optimize this several patterns are presented in here in relation to covered areas as well as in optimized distance between contact points and areas.

### SUMMARY

The invention provides a method for preparing a metallization structure on a solar cell. The method comprises: 1) patterning a first composition on a surface of a semiconductor substrate; and 2) applying a second composition over the first composition, wherein an area of the first composition is 5-95% of an area of the second composition. Upon firing, the first composition forms a conductive contact layer, and the second composition forms an electroconductive layer.

The invention provides a metallization structure on a solar cell, wherein the metallization structure comprising controlled or confined ARC openings; a conductive contact layer on a surface of a semiconductor substrate; and an electroconductive layer over the conductive contact layer, wherein an area of the conductive contact layer is 5-95% of an area of the electroconductive layer.

The invention also provides a solar cell prepared according to the methods disclosed herein.

### DESCRIPTION OF DRAWINGS

FIG. 1A is a planar view and a side view of a solar cell upon which a first composition is applied in a dotted pattern. FIG. 1B is a planar view and a side view of a solar cell after a second composition is applied over the first composition.

FIGS. 2A, 2B and 2C are each a planar view and a side view of a solar cell upon which a first composition is applied in a dashed line pattern, and a second composition is applied over the first composition.

FIGS. 3A, 3B and 3C are each a planar view and a side view of a solar cell upon which a first composition is applied in a narrow line pattern, and a second composition is applied over the first composition.

FIG. 4 is a planar view and a side view of a solar cell upon which a first composition is applied in a zigzag pattern, and a second composition is applied over the first composition.

FIG. 5A is a planar view of a solar cell with a standard print of a contact layer paste (Screen A). FIG. 5B is a planar view of a solar cell with a patterned print of a contact layer paste of the current invention (Screen B). FIG. 5C is a planar view of a solar cell with another patterned print of a contact layer paste of the current invention (Screen C).

FIG. 6 is a planar view of a solar cell upon with a patterned print of a contact layer paste and a second print of an electroconductive paste of the current invention (Screen D).

### DETAILED DESCRIPTION

The invention relates to a method of preparing a metallization structure on a solar cell. The method comprises two steps. In the first step, a contact forming layer is formed which upon firing creates openings in the passivation layer or ARC layer of the silicon wafer. In the second step, an electroconductive layer is prepared over the conductive contact layer. The metallization structure comprises the two layers. Further, an area of the conductive contact layer is 5-95% of an area of the electroconductive layer.

The bottom conductive contact layer upon firing opens the ARC or passivation layer partially and establishes electrical connection between the underlying electron- or hole-generating semiconductor silicon wafer and the top electroconductive layer which is the current-carrying gridlines.

The materials used in the bottom conductive contact layer and the top electroconductive layer may be the same or different.

### Conductive Contact Layer

The conductive contact layer is formed by first applying a first composition in a pattern on the surface of the semiconductor substrate. The first composition may be a contact layer paste printed or otherwise deposited in a preset pattern. During firing, the contact layer paste etches the passivation layer or ARC layer to create the contact openings. The first composition may be applied on the surface of the semiconductor substrate in any pattern desired or practical. The placement and pattern of the first composition determine the areas of etching thus contact opening during firing. Some examples are described below.

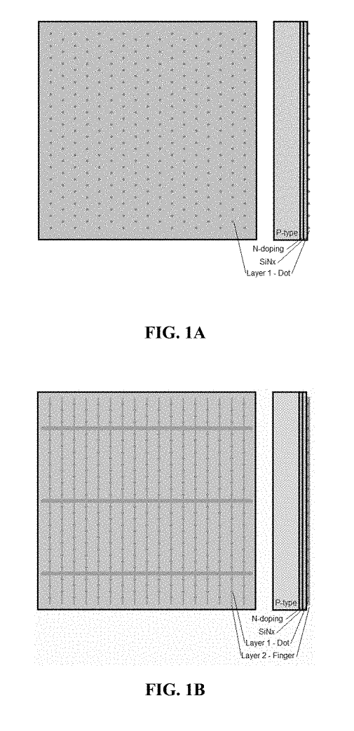

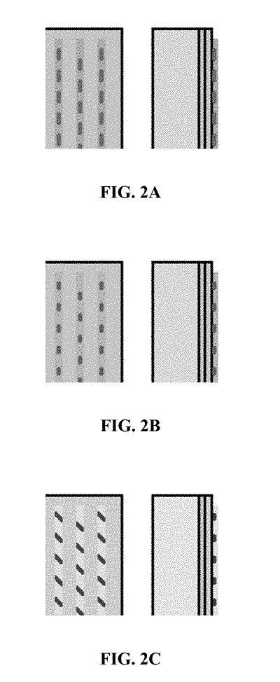

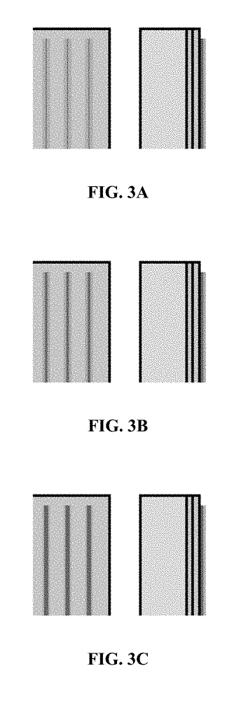

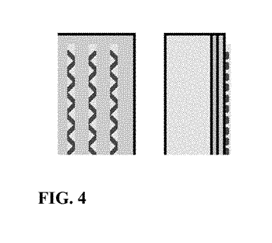

The pattern may be a plurality of dots as shown in FIG. 1A to form a dot matrix, a plurality of dashed lines as shown in FIG. 2, a plurality of narrow lines as shown in FIG. 3, a plurality of zigzag lines as shown in FIG. 4, or a combination of a plurality of dots and a plurality of lines, or other shapes.

In some embodiments, each of the plurality of dots may have a similar shape, width and/or diameter. The diameter or shape of each of the plurality of dots is not particularly limited. For example, the diameter may be in a range of microns to millimeters, from about 1 μm to about 2 mm, from about 5 μm to about 800 μm or from about 10 μm to about 500 μm.

The width of the lines are not particularly limited. In some embodiments, the width of each line of the plurality of lines may be in a range from about 1 μm to about 200 μm, from about 5 μm to about 100 μm or from about 10 μm to about 50 μm. In some embodiments, each of the contact openings may include a perimeter having other geometric shapes besides holes and/or narrow lines.

In some embodiments, other patterning apparatus or methods can also be employed to form the one or more contact openings, as described earlier. For example, the one or more openings can be formed by chemical etching through direct printing of an etchant material onto the passivation and/or ARC layer of the semiconductor substrate, using ink jet printing, screen printing, pad printing or other printing method. Alternatively, the chemical etching may also be performed by direct printing an etching protective mask onto the passivation and/or ARC layer of the semiconductor substrate and then putting the substrate into an etching solution. The etching protection mask can also be formed by spin coating, spray coating or evaporating a protection layer followed by patterning the protection layer.

In the case of direct printing, a contact layer paste may be used. In one embodiment, the contact layer paste may contain a lower silver content and a higher liquid content than in a standard electroconductive paste. In the current specification, this low silver and high liquid paste is also referred to as a seed layer paste. The term “low silver and high liquid paste” and “a seed layer paste” are used interchangeably. In another embodiment, the contact layer paste may be a standard electroconductive paste.

1. Lower Silver/High Liquid Paste

The low silver and high liquid paste comprises: 1) a silver particle at 0.1-50 wt %; 2) at least one glass frit at 5-70 wt %; and 3) an organic vehicle at 20-95 wt %. Typically, the silver particle is at about 0.1 wt % to about 50 wt %, within which any range or value is contemplated. The silver particle may be a mixture of particles of varying size, surface area, or other characteristics. In one embodiment, the silver particle is at least about 0.5 wt %, preferably at least about 1 wt %, more preferably at least about 3 wt %, more preferably at least about 5 wt %, most preferably at least about 10 wt %. In another embodiment, the silver particle is no more than about 35 wt %, preferably no more than about 25 wt %, more preferably no more than about 20 wt %. For example, in a preferred embodiment the silver particle is about 3 wt % to about 25 wt %, or about 5 wt % to about 20 wt %. All weight percentages are percentages of the seed layer paste.

In such a paste of a lower silver content and a higher glass content, the glass frit is at about 5 wt % to about 70 wt %, within which any range or value is contemplated. In one embodiment, the glass frit is at least about 10 wt %, preferably at least about 15 wt %, more preferably at least about 20 wt %. In another embodiment, the glass frit is no more than about 60 wt %, preferably no more than about 50 wt %, more preferably no more than about 40 wt %, most preferably no more than about 30 wt %. For example, in a preferred embodiment the glass frit is about 5 wt % to about 50 wt %, or about 10 wt % to about 30 wt %. All weight percentages are percentages of the seed layer paste.

The organic vehicle is at about 20 wt % to about 95 wt %, within which any range or value is contemplated. In one embodiment, the organic vehicle is at least about 35 wt %, preferably at least about 45 wt %, more preferably at least about 55 wt %. In another embodiment, the organic vehicle is no more than about 85 wt %, preferably no more than about 75 wt %, more preferably no more than about 65 wt %. For example, in a preferred embodiment the organic vehicle is about 35 wt % to about 75 wt %, or about 55 wt % to about 90 wt %. All weight percentages are percentages of the seed layer paste.

In one embodiment, the glass frit and the silver particle are in a weight ratio of 0.1:1 to 700:1, within which any range or value is contemplated. In a preferred embodiment, the glass frit and the silver particle are in a weight ratio of at least 0.4:1, preferably at least 1:1, most preferably at least 3:1, most preferably at least 10:1. In another embodiment, the glass frit and the silver particle are in a weight ratio no more than 500:1 by weight, preferably no more than 100:1, more preferably no more than 50:1, most preferably no more than 30:1. In another preferred embodiment, the glass frit and the silver particle are in a weight ratio of 0.5:1 to 10:1.

In another embodiment, the organic vehicle and the glass frit are in a weight ratio of 1:1 to 16:1, within which any range or value is contemplated. In a preferred embodiment, the organic vehicle and the glass frit are in a weight ratio of at least 3:1, preferably at least 5:1, more preferably at least 8:1. In another preferred embodiment, the organic vehicle and the glass frit are in a weight ratio no more than 12:1, preferably no more than 10:1.

2. Standard-Type Electroconductive Paste

A paste similar to the standard electroconductive paste may also be used as the conductive contact paste. The electroconductive paste comprises about 50-95 wt % a silver particle, about 0.05-10 wt % glass frit, about 5-50 wt % organic vehicle, and optionally approximately 0.01-5 wt % of an adhesion enhancer, based upon 100% total weight of the electroconductive paste. Within each range, any subrange or value is contemplated for each component.

In a preferred embodiment, the electroconductive paste comprises at least about 60 wt %, more preferably at least about 75 wt %, most preferably at least about 85 wt % silver particle. The silver particle comprises at least one type of silver particles.

In another preferred embodiment, the electroconductive paste comprises at least about 0.1 wt %, or at least about 1 wt % glass.

In one embodiment, the silver particle and glass frit are in a weight ratio of 20:1 to 1000:1, within which any range or value is contemplated. In a preferred embodiment, the silver particle and glass frit are in a weight ratio of at least 50:1, at least 100:1, or at least 200:1. In another embodiment, the silver particle and glass frit are in a weight ratio no more than 750:1 by weight, or no more than 500:1.

The percentage of the area of the conductive contact layer out of the area of the electroconductive layer is about 5-95%. In a preferred embodiment, the area of the conductive contact paste is no greater than 90%, more preferably no greater than 85%. At the same time, the area of the conductive contact paste is preferably no less than 10%, more preferably no less than 20%, most preferably no less than 30%.

### Electroconductive Layer

A second composition is applied on top of the first composition. The second composition is an electroconductive paste that upon firing forms an electroconductive layer on top of the bottom contact layer. The electroconductive layer provides lateral conductivity and carries the charge to bus bars. The electroconductive paste composition according to the invention is generally comprised of metallic particles, at least one glass frit, and an organic vehicle. The electroconductive paste composition may further comprise an adhesion enhancer.

According to one embodiment, the electroconductive paste comprises about 50-95 wt % of a metallic particle, about 0.05-10 wt % of a glass frit, about 5-50 wt % of an organic vehicle, and optionally approximately 0.01-5 wt % of an adhesion enhancer, based upon 100% total weight of the electroconductive paste.

Metals which may be employed as the metallic particles include at least one of silver, copper, gold, aluminum, nickel, platinum, palladium, molybdenum, and mixtures or alloys thereof. In a preferred embodiment, the metallic particles are silver. The silver may be present as elemental silver, a silver alloy, or silver derivate. Suitable silver derivatives include, for example, silver alloys and/or silver salts, such as silver halides (e.g., silver chloride), silver oxide, silver nitrate, silver acetate, silver trifluoroacetate, silver orthophosphate, and combinations thereof. In another embodiment, the metallic particles may comprise a metal or alloy coated with one or more different metals or alloys, for example copper particles coated with silver.

In a preferred embodiment, the electroconductive paste comprises at least about 60 wt %, more preferably at least about 75 wt %, most preferably at least about 85 wt % metal particle. In a preferred embodiment, the metallic particle is silver. Typically, the silver content is higher than that in the conductive contact paste.

In another preferred embodiment, the electroconductive paste comprises about 1-3 wt % of a glass frit.

The electroconductive paste is printed over the pattern on the bottom and covers a much larger area than the pattern on the bottom. Upon firing, the electroconductive paste forms the electroconductive layer that is the gridlines (finger lines and busbars), and the seed layer paste forms the conductive contact layer. In the case where both layers employ the standard electroconductive paste, the electroconductive paste forms both the electroconductive layer and conductive contact layer. The percentage of the area of the conductive contact layer out of the area of the electroconductive layer is about 5-95%. In a preferred embodiment, the percentage is about 10-50%, more preferably about 20-25%. The electroconductive paste and thus the electroconductive layer is represented by the solid lines that cover larger areas in FIGS. 1-4.

The bottom conductive contact layer and the top electroconductive layer together form a metallization structure upon firing.

### Organic Vehicle for Conductive Contact Layer Paste and Electroconductive Paste

The organic vehicle of the invention provides the media by which the seed layer paste or the electroconductive paste is applied to the silicon surface to form a contact layer, or on top of the seed layer respectively. The organic vehicle used for the conductive contact layer paste may be the same or different from that used for the electroconductive paste. Preferred organic vehicles are solutions, emulsions or dispersions formed of one or more solvents, preferably organic solvent(s), which ensure that the components of the paste are present in a dissolved, emulsified or dispersed form. Organic vehicles which provide optimal stability of the components of the seed layer paste and which provide the paste with suitable printability are preferred.

In one embodiment, the organic vehicle comprises an organic solvent and one or more of a binder (e.g., a polymer), a surfactant and a thixotropic agent, or any combination thereof. For example, in one embodiment, the organic vehicle comprises one or more binders in an organic solvent.

Preferred binders in the context of the invention are those which contribute to the formation of an electroconductive paste with favorable stability, printability, and viscosity properties. Binders are well known in the art. All binders which are known in the art, and which are considered to be suitable in the context of this invention, can be employed as the binder in the organic vehicle. Preferred binders according to the invention (which often fall within the category termed “resins”) are polymeric binders, monomeric binders, and binders which are a combination of polymers and monomers. Polymeric binders can also be copolymers wherein at least two different monomeric units are contained in a single molecule. Preferred polymeric binders are those which carry functional groups in the polymer main chain, those which carry functional groups off of the main chain and those which carry functional groups both within the main chain and off of the main chain. Preferred polymers carrying functional groups in the main chain are for example polyesters, substituted polyesters, polycarbonates, substituted polycarbonates, polymers which carry cyclic groups in the main chain, poly-sugars, substituted poly-sugars, polyurethanes, substituted polyurethanes, polyamides, substituted polyamides, phenolic resins, substituted phenolic resins, copolymers of the monomers of one or more of the preceding polymers, optionally with other co-monomers, or a combination of at least two thereof. According to one embodiment, the binder may be polyvinyl butyral or polyethylene. Preferred polymers which carry cyclic groups in the main chain are for example polyvinylbutylate (PVB) and its derivatives and poly-terpineol and its derivatives or mixtures thereof. Preferred poly-sugars are for example cellulose and alkyl derivatives thereof, preferably methyl cellulose, ethyl cellulose, hydroxyethyl cellulose, propyl cellulose, hydroxypropyl cellulose, butyl cellulose and their derivatives and mixtures of at least two thereof. Other preferred polymers are cellulose ester resins, e.g., cellulose acetate propionate, cellulose acetate buyrate, and any combinations thereof. Preferred polymers which carry functional groups off of the main polymer chain are those which carry amide groups, those which carry acid and/or ester groups, often called acrylic resins, or polymers which carry a combination of aforementioned functional groups, or a combination thereof. Preferred polymers which carry amide off of the main chain are for example polyvinyl pyrrolidone (PVP) and its derivatives. Preferred polymers which carry acid and/or ester groups off of the main chain are for example polyacrylic acid and its derivatives, polymethacrylate (PMA) and its derivatives or polymethylmethacrylate (PMMA) and its derivatives, or a mixture thereof. Preferred monomeric binders according to the invention are ethylene glycol based monomers, terpineol resins or rosin derivatives, or a mixture thereof. Preferred monomeric binders based on ethylene glycol are those with ether groups, ester groups or those with an ether group and an ester group, preferred ether groups being methyl, ethyl, propyl, butyl, pentyl hexyl and higher alkyl ethers, the preferred ester group being acetate and its alkyl derivatives, preferably ethylene glycol monobutylether monoacetate or a mixture thereof. Alkyl cellulose, preferably ethyl cellulose, its derivatives and mixtures thereof with other binders from the preceding lists of binders or otherwise are the most preferred binders in the context of the invention.

Preferred solvents are components which are removed from the paste to a significant extent during firing. Preferably, they are present after firing with an absolute weight reduced by at least about 80% compared to before firing, preferably reduced by at least about 95% compared to before firing. Preferred solvents are those which contribute to favorable viscosity and printability characteristics. All solvents which are known in the art, and which are considered to be suitable in the context of this invention, may be employed as the solvent in the organic vehicle. Preferred solvents are those which exist as a liquid under standard ambient temperature and pressure (SATP) (298.15 K, 25° C., 77° F.), 100 kPa (14.504 psi, 0.986 atm), preferably those with a boiling point above about 90° C. and a melting point above about −20° C. Preferred solvents are polar or non-polar, protic or aprotic, aromatic or non-aromatic. Preferred solvents include, for example, mono-alcohols, di-alcohols, poly-alcohols, mono-esters, di-esters, poly-esters, mono-ethers, di-ethers, poly-ethers, solvents which comprise at least one or more of these categories of functional group, optionally comprising other categories of functional group, preferably cyclic groups, aromatic groups, unsaturated bonds, alcohol groups with one or more O atoms replaced by heteroatoms, ether groups with one or more O atoms replaced by heteroatoms, esters groups with one or more O atoms replaced by heteroatoms, and mixtures of two or more of the aforementioned solvents. Preferred esters in this context include, for example, di-alkyl esters of adipic acid, preferred alkyl constituents being methyl, ethyl, propyl, butyl, pentyl, hexyl and higher alkyl groups or combinations of two different such alkyl groups, preferably dimethyladipate, and mixtures of two or more adipate esters. Preferred ethers in this context include, for example, diethers, preferably dialkyl ethers of ethylene glycol, preferred alkyl constituents being methyl, ethyl, propyl, butyl, pentyl, hexyl and higher alkyl groups or combinations of two different such alkyl groups, and mixtures of two diethers. Preferred alcohols in this context include, for example, primary, secondary and tertiary alcohols, preferably tertiary alcohols, terpineol and its derivatives being preferred, or a mixture of two or more alcohols. Preferred solvents which combine more than one different functional groups are tripropylene glycol methyl ether (TPM), 2,2,4-trimethyl-1,3-pentanediol monoisobutyrate, often called texanol, and its derivatives, 2-(2-ethoxyethoxy)ethanol, often known as carbitol, its alkyl derivatives, preferably methyl, ethyl, propyl, butyl, pentyl, and hexyl carbitol, preferably hexyl carbitol or butyl carbitol, and acetate derivatives thereof, preferably butyl carbitol acetate, or mixtures of at least two of the aforementioned. In a preferred embodiment, the solvent includes at least one of butyl carbitol, butyl carbitol acetate, terpineol, or mixtures thereof. These three solvents are believed to mix well with the styrene-butadiene-styrene block copolymer.

The organic solvent may be present in an amount of at least about 50 wt %, and more preferably at least about 60 wt %, and more preferably at least about 70 wt %, based upon 100% total weight of the organic vehicle. At the same time, the organic solvent may be present in an amount of no more than about 95 wt %, and more preferably no more than about 90 wt %, based upon 100% total weight of the organic vehicle.

The organic vehicle may also comprise a surfactant and/or additives. Suitable surfactants are those which contribute to the formation of a seed layer paste with favorable printability and viscosity characteristics. All surfactants which are known in the art, and which are considered to be suitable in the context of this invention, may be employed as the surfactant in the organic vehicle. Preferred surfactants are those based on linear chains, branched chains, aromatic chains, fluorinated chains, polyether chains and combinations thereof. Preferred surfactants include, but are not limited to, single chained, double chained or poly chained polymers. Preferred surfactants may have non-ionic, anionic, cationic, amphiphilic, or zwitterionic heads. Preferred surfactants may be polymeric and monomeric or a mixture thereof. Preferred surfactants may have pigment affinic groups, preferably hydroxyfunctional carboxylic acid esters with pigment affinic groups (e.g., DISPERBYK®-108, manufactured by BYK USA, Inc.), acrylate copolymers with pigment affinic groups (e.g., DISPERBYK®-116, manufactured by BYK USA, Inc.), modified polyethers with pigment affinic groups (e.g., TEGO® DISPERS 655, manufactured by Evonik Tego Chemie GmbH), and other surfactants with groups of high pigment affinity (e.g., Duomeen TDO® manufactured by Akzo Nobel N.V.). Other preferred polymers not in the above list include, but are not limited to, polyethylene oxide, polyethylene glycol and its derivatives, and alkyl carboxylic acids and their derivatives or salts, or mixtures thereof. The preferred polyethylene glycol derivative is poly(ethyleneglycol)acetic acid. Preferred alkyl carboxylic acids are those with fully saturated and those with singly or poly unsaturated alkyl chains or mixtures thereof. Preferred carboxylic acids with saturated alkyl chains are those with alkyl chains lengths in a range from about 8 to about 20 carbon atoms, preferably C₉H₁₉COOH (capric acid), C₁₁H₂₃COOH (lauric acid), C₁₃H₂₇COOH (myristic acid) C₁₅H₃₁COOH (palmitic acid), C₁₇H₃₅COOH (stearic acid), or salts or mixtures thereof. Preferred carboxylic acids with unsaturated alkyl chains are C₁₈H₃₄O₂ (oleic acid) and C₁₈H₃₂O₂ (linoleic acid).

The organic vehicle may also comprise one or more thixotropic agents and/or other additives. Any thixotropic agent known to one having ordinary skill in the art may be used with the organic vehicle of the invention. For example, without limitation, thixotropic agents may be derived from natural origin or they may be synthesized. Preferred thixotropic agents include, but are not limited to, castor oil and its derivatives, inorganic clays, polyamides and its derivatives, fumed silica, carboxylic acid derivatives, preferably fatty acid derivatives (e.g., C₉H₁₉COOH (capric acid), C₁₁H₂₃COOH (lauric acid), C₁₃H₂₇COOH (myristic acid) C₁₅H₃₁COOH (palmitic acid), C₁₇H₃₅COOH (stearic acid) C₁₈H₃₄O₂ (oleic acid), C₁₈H₃₂O₂ (linoleic acid)), or combinations thereof. Commercially available thixotropic agents, such as, for example, Thixotrol® MAX, Thixotrol® ST, or THIXCIN® E, may also be used.

Preferred additives in the organic vehicle are those materials which are distinct from the aforementioned components and which contribute to favorable properties of the electroconductive composition, such as advantageous viscosity, printability, and stability characteristics. Additives known in the art, and which are considered to be suitable in the context of the invention, may be used. Preferred additives include, but are not limited to, viscosity regulators, stabilizing agents, inorganic additives, thickeners, emulsifiers, dispersants and pH regulators.

According to one embodiment, the viscosity of the seed layer paste or the electroconductive paste is preferably at least 15 kcps and no more than about 100 kcps, preferably at least about 15 kcps, and no more than about 50 kcps.

### Silver Particles for Contact Layer Paste and Electroconductive Paste

The contact layer paste or the electroconductive paste comprises a silver particle. The silver particle used for the contact layer paste may be the same or different from that used for the electroconductive paste. The preferred silver particles include, but are not limited to, elemental metals, alloys, metal derivatives, mixtures of at least two metals, mixtures of at least two alloys or mixtures of at least one metal with at least one alloy.

Suitable silver derivatives include, for example, silver alloys and/or silver salts, such as silver halides (e.g., silver chloride), silver oxide, silver nitrate, silver acetate, silver trifluoroacetate, silver orthophosphate, and combinations thereof. In another embodiment, the silver particles may comprise a metal or alloy coated with one or more different metals or alloys, for example copper particles coated with silver.

The silver particles may be present with a surface coating, either organic or inorganic. Any such coating known in the art, and which is considered to be suitable in the context of the invention, may be employed on the metallic particles. Preferred organic coatings are those coatings which promote dispersion into the organic vehicle. Preferred inorganic coatings are those coatings which regulate sintering and promote adhesive performance of the resulting seed layer paste. If such a coating is present, it is preferred that the coating correspond to no more than about 5 wt %, preferably no more than about 2 wt %, and most preferably no more than about 1 wt %, based on 100% total weight of the metallic particles.

The silver particles can exhibit a variety of shapes, sizes, and specific surface areas. Some examples of shapes include, but are not limited to, spherical, angular, elongated (rod or needle like) and flat (sheet like). The silver particles may also be present as a combination of particles with different shapes, such as, for example, a combination of spherical metallic particles and flake-shaped metallic particles.

Another characteristic of the silver particles is its average particle size, d₅₀. The d₅₀ is the median diameter or the medium value of the particle size distribution. It is the value of the particle diameter at 50% in the cumulative distribution. Particle size distribution may be measured via laser diffraction, dynamic light scattering, imaging, electrophoretic light scattering, or any other methods known in the art. Specifically, particle size according to the invention is determined in accordance with ISO 13317-3:2001. As set forth herein, a Horiba LA-910 Laser Diffraction Particle Size Analyzer connected to a computer with an LA-910 software program is used to determine the median particle diameter. The relative refractive index of the metallic particle is chosen from the LA-910 manual and entered into the software program. The test chamber is filled with deionized water to the proper fill line on the tank. The solution is then circulated by using the circulation and agitation functions in the software program. After one minute, the solution is drained. This is repeated an additional time to ensure the chamber is clean of any residual material. The chamber is then filled with deionized water for a third time and allowed to circulate and agitate for one minute. Any background particles in the solution are eliminated by using the blank function in the software. Ultrasonic agitation is then started, and the metallic particles are slowly added to the solution in the test chamber until the transmittance bars are in the proper zone in the software program. Once the transmittance is at the correct level, the laser diffraction analysis is run and the particle size distribution of the metallic component is measured and given as d₅₀.

It is preferred that the median particle diameter d₅₀ of the silver particles be at least about 0.1 μm, and preferably at least about 0.5 μm. At the same time, the d₅₀ is preferably no more than about 5 μm, and more preferably no more than about 4 μm.

In a preferred embodiment, the silver particles comprise a combination of at least two types of silver particles such as silver particles having different particle sizes.

Another way to characterize the shape and surface of a particle is by its specific surface area. Specific surface area is a property of solids equal to the total surface area of the material per unit mass, solid, or bulk volume, or cross sectional area. It is defined either by surface area divided by mass (with units of m²/g) or surface area divided by volume (units of m⁻¹). The specific surface area may be measured by the BET (Brunauer-Emmett-Teller) method, which is known in the art. As set forth herein, BET measurements are made in accordance with DIN ISO 9277:1995. A Monosorb Model MS-22 instrument (manufactured by Quantachrome Instruments), which operates according to the SMART method (Sorption Method with Adaptive dosing Rate), is used for the measurement. As a reference material, aluminum oxide (available from Quantachrome Instruments as surface area reference material Cat. No. 2003) is used. Samples are prepared for analysis in the built-in degas station. Flowing gas (30% N₂ and 70% He) sweeps away impurities, resulting in a clean surface upon which adsorption may occur. The sample can be heated to a user-selectable temperature with the supplied heating mantle. Digital temperature control and display are mounted on the instrument front panel. After degassing is complete, the sample cell is transferred to the analysis station. Quick connect fittings automatically seal the sample cell during transfer, and the system is then activated to commence the analysis. A dewar flask filled with coolant is manually raised, immersing the sample cell and causing adsorption. The instrument detects when adsorption is complete (2-3 minutes), automatically lowers the dewar flask, and gently heats the sample cell back to room temperature using a built-in hot-air blower. As a result, the desorbed gas signal is displayed on a digital meter and the surface area is directly presented on a front panel display. The entire measurement (adsorption and desorption) cycle typically requires less than six minutes. The technique uses a high sensitivity, thermal conductivity detector to measure the change in concentration of an adsorbate/inert carrier gas mixture as adsorption and desorption proceed. When integrated by the on-board electronics and compared to calibration, the detector provides the volume of gas adsorbed or desorbed. For the adsorptive measurement, N₂ 5.0 with a molecular cross-sectional area of 0.162 nm² at 77K is used for the calculation. A one-point analysis is performed and a built-in microprocessor ensures linearity and automatically computes the sample's BET surface area in m²/g.

According to one embodiment, the silver particles may have a specific surface area of at least about 0.1 m²/g, preferably at least about 0.2 m²/g. At the same time, the specific surface area is preferably no more than 10 m²/g, and more preferably no more than about 5 m²/g.

In addition to silver, other metals which may be employed as the metallic particles in the electroconductive paste include at least one of copper, gold, aluminum, nickel, platinum, palladium, molybdenum, and mixtures or alloys thereof. In another embodiment, the metallic particles may comprise a metal or alloy coated with one or more different metals or alloys, for example copper particles coated with silver.

### Glass Frit for Contact Layer Paste and Electroconductive Paste

The glass frit of the contact layer paste limits lateral conductivity due to the silver conductivity but establishes point contacts with the underlying silicon wafer. The glass frit etches through the surface layers (e.g., diffusion layer and/or antireflective layer) of the silicon substrate, such that effective electrical contact can be made between the electroconductive paste and the silicon wafer.

The glass frit of the electroconductive paste acts as an adhesion media, facilitating the bonding between the conductive particles and etching the silicon substrate, and thus providing reliable electrical contact.

The glass frit used for the contact layer paste may be the same or different from that used for the electroconductive paste.

Preferred glass frits are etchant materials, which may be an amorphous powder that exhibits a glass transition, crystalline or partially crystalline solids, or a mixture thereof. The glass transition temperature T_{g} is the temperature at which an amorphous substance transforms from a rigid solid to a partially mobile undercooled melt upon heating. Methods for the determination of the glass transition temperature are well known to the person skilled in the art. Specifically, the glass transition temperature T_{g} may be determined using a DSC apparatus SDT Q600 (commercially available from TA Instruments) which simultaneously records differential scanning calorimetry (DSC) and thermogravimetric analysis (TGA) curves. The instrument is equipped with a horizontal balance and furnace with a platinum/platinum-rhodium (type R) thermocouple. The sample holders used are aluminum oxide ceramic crucibles with a capacity of about 40-90 μl. For the measurements and data evaluation, the measurement software Q Advantage; Thermal Advantage Release 5.4.0 and Universal Analysis 2000, version 4.5A Build 4.5.0.5 is applied respectively. As pan for reference and sample, aluminum oxide pan having a volume of about 85 μl is used. An amount of about 10-50 mg of the sample is weighted into the sample pan with an accuracy of 0.01 mg. The empty reference pan and the sample pan are placed in the apparatus, the oven is closed and the measurement started. A heating rate of 10 K/min is employed from a starting temperature of 25° C. to an end temperature of 1000° C. The balance in the instrument is always purged with nitrogen (N₂ 5.0) and the oven is purged with synthetic air (80% N₂ and 20% O₂ from Linde) with a flow rate of 50 ml/min. The first step in the DSC signal is evaluated as glass transition using the software described above, and the determined onset value is taken as the temperature for T_{g}.

Preferably, the T_{g} is below the desired firing temperature of the electroconductive paste. According to the invention, preferred glass frits have a T_{g} of at least about 200° C., and preferably at least about 250° C. At the same time, preferred glass frits have a T_{g} of no more than about 900° C., preferably no more than about 800° C., and most preferably no more than about 700° C.

The glass frit may include elements, oxides, compounds which generate oxides upon heating, and/or mixtures thereof. According to one embodiment, the glass frit is lead-based and may include lead oxide or other lead-based compounds including, but not limited to, salts of lead halides, lead chalcogenides, lead carbonate, lead sulfate, lead phosphate, lead nitrate and organometallic lead compounds or compounds that can form lead oxides or salts during thermal decomposition, or any combinations thereof. In another embodiment, the glass frit may be lead-free. The term “lead-free” indicates that the glass frit has less than 0.5 wt % lead, based upon 100% total weight of the glass frit. The glass frit may include other oxides or compounds known to one skilled in the art, including, but not limited to, silicon, boron, aluminum, bismuth, lithium, sodium, magnesium, zinc, titanium, zirconium oxides, or compounds thereof.

In addition to the components recited above, the glass frit may also comprise other oxides or other compounds of magnesium, nickel, tellurium, tungsten, zinc, gadolinium, antimony, cerium, zirconium, titanium, manganese, lead, tin, ruthenium, silicon, cobalt, iron, copper, bismuth, boron, and chromium, or any combination of at least two thereof, compounds which can generate those metal oxides upon firing, or a mixture of at least two of the aforementioned metals, a mixture of at least two of the aforementioned oxides, a mixture of at least two of the aforementioned compounds which can generate those metal oxides on firing, or mixtures of two or more of any of the above mentioned. Other materials which may be used to form the inorganic oxide particles include, but are not limited to, germanium oxide, vanadium oxide, molybdenum oxide, niobium oxide, indium oxide, other alkaline and alkaline earth metal (e.g., potassium, rubidium, caesium, calcium, strontium, and barium) compounds, rare earth oxides (e.g., lanthanum oxide, cerium oxides), and phosphorus oxides.

It is well known to the person skilled in the art that glass frit particles can exhibit a variety of shapes, sizes, and surface area to volume ratios. The glass particles may exhibit the same or similar shapes (including length:width:thickness ratio) as may be exhibited by the conductive metallic particles, as discussed herein. Glass frit particles with a shape, or combination of shapes, which favor improved electrical contact of the produced electrode are preferred. It is preferred that the median particle diameter d₅₀ of the glass frit particles (as set forth above with respect to the conductive metallic particles) be at least about 0.1 μm. At the same time, it is preferred that the d₅₀ of the glass frit be no more than about 10 μm, more preferably no more than about 5 μm, and most preferably no more than about 3.5 μm. In one embodiment, the glass frit particles have a specific surface area of at least about 0.5 m²/g, preferably at least about 1 m²/g, and most preferably at least about 2 m²/g. At the same time, it is preferred that the specific surface area be no more than about 15 m²/g, preferably no more than about 10 m²/g.

According to another embodiment, the glass frit particles may include a surface coating. Any such coating known in the art and which is considered to be suitable in the context of the invention can be employed on the glass frit particles. Preferred coatings according to the invention include those coatings which promote dispersion of the glass in the organic vehicle and improved contact of the electroconductive paste. If such a coating is present, it is preferred that the coating correspond to no more than about 10 wt %, preferably no more than about 8 wt %, most preferably no more than about 5 wt %, in each case based on the total weight of the glass frit particles.

In a preferred embodiment, a Pb—Te-alkaline-alkaline earth glass frit is used in the contact layer paste, for example a Pb—Te—Li—Bi glass frit or a Pb-free Te—Li—Zn glass frit. Any other glass frit or a mixture of different types of glass frit may also be used.

In another preferred embodiment, a Pb—Bi—Zn—W—Mg glass frit is used in the electroconductive paste.

### Additives

Preferred additives are components added to the paste, in addition to the other components explicitly mentioned, which contribute to increased electrical performance of the paste, of the electrodes produced thereof, or of the resulting solar cell. In addition to additives present in the glass frit and in the vehicle, additives can also be present in the electroconductive paste separately. Preferred additives include, but are not limited to, thixotropic agents, surfactants, viscosity regulators, emulsifiers, stabilizing agents or pH regulators, inorganic additives, thickeners and dispersants, or a combination of at least two thereof. Preferred inorganic oxides or organometallic additives include, but are not limited to, Mg, Ni, Te, W, Zn, Mg, Gd, Ce, Zr, Ti, Mn, Sn, Ru, Co, Fe, Rh, V, Y, Sb, P, Cu and Cr or a combination of at least two thereof, preferably Zn, Sb, Mn, Ni, W, Te, Rh, V, Y, Sb, P and Ru, or a combination of at least two thereof, oxides thereof, compounds which can generate those metal oxides on firing, or a mixture of at least two of the aforementioned metals, a mixture of at least two of the aforementioned oxides, a mixture of at least two of the aforementioned compounds which can generate those metal oxides on firing, or mixtures of two or more of any of the above mentioned. In a preferred embodiment, the electroconductive paste comprises zinc oxide.

According to one embodiment, the paste may include at least about 0.01 wt % additive(s). At the same time, the paste preferably includes no more than about 10 wt % additive(s), preferably no more than about 5 wt %, and most preferably no more than about 2 wt %, based upon 100% total weight of the paste. For example, the electroconductive paste may optionally comprise about 0.01-5 wt % of an adhesion enhancer.

### Forming Conductive Contact Layer Paste or Electroconductive Paste

To form a conductive contact layer paste or electroconductive paste, the glass frit materials are combined with the silver particles and organic vehicle using any method known in the art for preparing a paste composition. The method of preparation is not critical, as long as it results in a homogenously dispersed paste. The components can be mixed, such as with a mixer, then passed through a three roll mill, for example, to make a dispersed uniform paste. In addition to mixing all of the components together simultaneously, the raw glass frit materials can be co-milled with silver particles, for example, in a ball mill for 2-24 hours to achieve a homogenous mixture of glass frit and silver particles, which are then mixed with the organic vehicle.

### Solar Cells

The invention also relates to a solar cell. In one embodiment, the solar cell comprises a semiconductor substrate (e.g., a silicon wafer), and a metallization structure according to any of the embodiments described herein.

In one aspect, the invention provides a method of preparing a metallization structure on a solar cell, comprising
a. patterning a first composition on a surface of a semiconductor substrate;
b. applying a second composition over the first composition, wherein an area covered by the first composition is about 5-95% of an area covered by the second composition; and
c. firing the semiconductor substrate bearing the first composition and the second composition.

The percentage of the area of the first composition or the conductive contact layer out of the area of the second composition or the electroconductive layer is about 5-95%. Any sub-range or value within the range is contemplated. In a preferred embodiment, the area of the conductive contact paste is no greater than 80%, more preferably no greater than 70%. At the same time, the area of the conductive contact paste is preferably no less than 20%, more preferably no less than 30%, most preferably no less than 40%. In a preferred embodiment, the area of the first composition or the conductive contact layer out of the area of the second composition or the electroconductive layer is about 30-95%, more preferably about 50-90%.

In another aspect, the method further comprises firing the silicon wafer with the first composition and the second composition.

In another aspect, the invention relates to a metallization structure comprising a first composition on a surface of a semiconductor substrate, a second composition over the first composition, wherein an area covered by the first composition is about 5-95%, preferably about 25-95%, more preferably about 35-90% of an area covered by the second composition. The first composition and the second composition are according to the aspects described above.

### Silicon Wafer

Preferred wafers according to the invention have regions, among other regions of the solar cell, capable of absorbing light with high efficiency to yield electron-hole pairs and separating holes and electrons across a boundary with high efficiency, preferably across a p-n junction boundary. Preferred wafers according to the invention are those comprising a single body made up of a front doped layer and a back doped layer.

Preferably, the wafer comprises appropriately doped tetravalent elements, binary compounds, tertiary compounds or alloys. Preferred tetravalent elements in this context include, but are not limited to, silicon, germanium, or tin, preferably silicon. Preferred binary compounds include, but are not limited to, combinations of two or more tetravalent elements, binary compounds of a group III element with a group V element, binary compounds of a group II element with a group VI element or binary compounds of a group IV element with a group VI element. Preferred combinations of tetravalent elements include, but are not limited to, combinations of two or more elements selected from silicon, germanium, tin or carbon, preferably SiC. The preferred binary compounds of a group III element with a group V element is GaAs. According to a preferred embodiment of the invention, the wafer is silicon. The foregoing description, in which silicon is explicitly mentioned, also applies to other wafer compositions described herein.

The p-n junction boundary is located where the front doped layer and back doped layer of the wafer meet. In an n-type solar cell, the back doped layer is doped with an electron donating n-type dopant and the front doped layer is doped with an electron accepting or hole donating p-type dopant. In a p-type solar cell, the back doped layer is doped with p-type dopant and the front doped layer is doped with n-type dopant. According to a preferred embodiment of the invention, a wafer with a p-n junction boundary is prepared by first providing a doped silicon substrate and then applying a doped layer of the opposite type to one face of that substrate.

The doped silicon substrate can be prepared by any method known in the art and considered suitable for the invention. Preferred sources of silicon substrates according to the invention include, but are not limited to, mono-crystalline silicon, multi-crystalline silicon, amorphous silicon and upgraded metallurgical silicon, most preferably mono-crystalline silicon or multi-crystalline silicon. Doping to form the doped silicon substrate can be carried out simultaneously by adding the dopant during the preparation of the silicon substrate, or it can be carried out in a subsequent step. Doping subsequent to the preparation of the silicon substrate can be carried out by gas diffusion epitaxy, for example. Doped silicon substrates are also readily commercially available. According to one embodiment, the initial doping of the silicon substrate may be carried out simultaneously to its formation by adding dopant to the silicon mix. According to another embodiment, the application of the front doped layer and the highly doped back layer, if present, may be carried out by gas-phase epitaxy. This gas phase epitaxy is preferably carried out at a temperature of at least about 500° C., preferably at least about 600° C., and most preferably at least about 650° C. At the same time, the temperature is preferably no more than about 900° C., preferably no more than about 800° C., and most preferably no more than about 750° C. The gas phase epitaxy is preferably carried out at a pressure of at least about 2 kPa, preferably at least about 10 kPa, and most preferably at least about 40 kPa. At the same, the pressure is preferably no more than about 100 kPa, preferably no more than about 80 kPa, and most preferably no more than about 70 kPa.

It is known in the art that silicon substrates can exhibit a number of shapes, surface textures and sizes. The shape of the substrate may include cuboid, disc, wafer and irregular polyhedron, to name a few. According to a preferred embodiment of the invention, the wafer is a cuboid with two dimensions which are similar, preferably equal, and a third dimension which is significantly smaller than the other two dimensions. The third dimension may be at least 100 times smaller than the first two dimensions. Further, silicon substrates with rough surfaces are preferred. One way to assess the roughness of the substrate is to evaluate the surface roughness parameter for a sub-surface of the substrate, which is small in comparison to the total surface area of the substrate, preferably less than about one hundredth of the total surface area, and which is essentially planar. The value of the surface roughness parameter is given by the ratio of the area of the sub-surface to the area of a theoretical surface formed by projecting that sub-surface onto the flat plane best fitted to the sub-surface by minimizing mean square displacement. A higher value of the surface roughness parameter indicates a rougher, more irregular surface and a lower value of the surface roughness parameter indicates a smoother, more even surface. According to the invention, the surface roughness of the silicon substrate is preferably modified so as to produce an optimum balance between a number of factors including, but not limited to, light absorption and adhesion to the surface.

The two larger dimensions of the silicon substrate can be varied to suit the application required of the resultant solar cell. It is preferred according to the invention for the thickness of the silicon wafer to be below about 0.5 mm, more preferably below about 0.3 mm, and most preferably below about 0.2 mm. Some wafers have a minimum thickness of 0.01 mm or more.

It is preferred that the front doped layer be thin in comparison to the back doped layer. It is also preferred that the front doped layer have a thickness of at least about 0.1 μm, and preferably no more than about 10 μm, preferably no more than about 5 μm, and most preferably no more than about 2 μm.

A highly doped layer can be applied to the back face of the silicon substrate between the back doped layer and any further layers. Such a highly doped layer is of the same doping type as the back doped layer and such a layer is commonly denoted with a + (n+-type layers are applied to n-type back doped layers and p+-type layers are applied to p-type back doped layers). This highly doped back layer serves to assist metallization and improve electroconductive properties. It is preferred according to the invention for the highly doped back layer, if present, to have a thickness of at least 1 μm, and preferably no more than about 100 μm, preferably no more than about 50 μm and most preferably no more than about 15 μm.

### Dopants

Preferred dopants are those which, when added to the silicon wafer, form a p-n junction boundary by introducing electrons or holes into the band structure. It is preferred that the identity and concentration of these dopants is specifically selected so as to tune the band structure profile of the p-n junction and set the light absorption and conductivity profiles as required. Preferred p-type dopants include, but are not limited to, those which add holes to the silicon wafer band structure. All dopants known in the art and which are considered suitable in the context of the invention can be employed as p-type dopants. Preferred p-type dopants include, but are not limited to, trivalent elements, particularly those of group 13 of the periodic table. Preferred group 13 elements of the periodic table in this context include, but are not limited to, boron, aluminum, gallium, indium, thallium, or a combination of at least two thereof, wherein boron is particularly preferred.

Preferred n-type dopants are those which add electrons to the silicon wafer band structure. Preferred n-type dopants are elements of group 15 of the periodic table. Preferred group 15 elements of the periodic table in this context include, but are not limited to, nitrogen, phosphorus, arsenic, antimony, bismuth or a combination of at least two thereof, wherein phosphorus is particularly preferred.

As described above, the various doping levels of the p-n junction can be varied so as to tune the desired properties of the resulting solar cell. Doping levels are measured using secondary ion mass spectroscopy.

According to certain embodiments, the semiconductor substrate (i.e., silicon wafer) exhibits a sheet resistance above about 60 Ω/□, such as above about 65 Ω/□, 70 Ω/□, 90 Ω/□ or 100 Ω/□. For measuring the sheet resistance of a doped silicon wafer surface, the device “GP4-Test Pro” equipped with software package “GP-4 Test 1.6.6 Pro” (available from GP Solar GmbH) is used. For the measurement, the four point measuring principle is applied. The two outer probes apply a constant current and two inner probes measure the voltage. The sheet resistance is deduced using the Ohmic law in Ω/□. To determine the average sheet resistance, the measurement is performed on 25 equally distributed spots of the wafer. In an air conditioned room with a temperature of 22±1° C., all equipment and materials are equilibrated before the measurement. To perform the measurement, the “GP-Test.Pro” is equipped with a 4-point measuring head (Part Number 04.01.0018) with sharp tips in order to penetrate the anti-reflection and/or passivation layers. A current of 10 mA is applied. The measuring head is brought into contact with the non metalized wafer material and the measurement is started. After measuring 25 equally distributed spots on the wafer, the average sheet resistance is calculated in Ω/□.

### Solar Cell Structure

A contribution to achieving at least one of the above described objects is made by a solar cell obtainable from a process according to the invention. Preferred solar cells according to the invention are those which have a high efficiency, in terms of proportion of total energy of incident light converted into electrical energy output, and those which are light and durable. At a minimum, a solar cell includes: (i) front electrodes, (ii) a front doped layer, (iii) a p-n junction boundary, (iv) a back doped layer, and (v) soldering pads. The solar cell may also include additional layers for chemical/mechanical protection.

### Antireflective Layer

According to the invention, an antireflective layer may be applied as the outer layer before the electrode is applied to the front face of the solar cell. All antireflective layers known in the art and which are considered to be suitable in the context of the invention can be employed. Preferred antireflective layers are those which decrease the proportion of incident light reflected by the front face and increase the proportion of incident light crossing the front face to be absorbed by the wafer. Antireflective layers which give rise to a favorable absorption/reflection ratio, are susceptible to etching by the electroconductive paste, are otherwise resistant to the temperatures required for firing of the electroconductive paste, and do not contribute to increased recombination of electrons and holes in the vicinity of the electrode interface, are preferred. Preferred antireflective layers include, but are not limited to, SiNₓ, SiO₂, Al₂O₃, TiO₂ or mixtures of at least two thereof and/or combinations of at least two layers thereof. According to a preferred embodiment, the antireflective layer is SiNₓ, in particular where a silicon wafer is employed.

The thickness of antireflective layers is suited to the wavelength of the appropriate light. According to a preferred embodiment of the invention, the antireflective layers have a thickness of at least 20 nm, preferably at least 40 nm, and most preferably at least 60 nm. At the same time, the thickness is preferably no more than about 300 nm, more preferably no more than about 200 nm, and most preferably no more than about 90 nm.

### Passivation Layers

One or more passivation layers may be applied to the front and/or back side of the silicon wafer as an outer layer. The passivation layer(s) may be applied before the front electrode is formed, or before the antireflective layer is applied (if one is present). Preferred passivation layers are those which reduce the rate of electron/hole recombination in the vicinity of the electrode interface. Any passivation layer which is known in the art and which is considered to be suitable in the context of the invention can be employed. Preferred passivation layers according to the invention include, but are not limited to, silicon nitride, silicon dioxide and titanium dioxide. According to a more preferred embodiment, silicon nitride is used. It is preferred for the passivation layer to have a thickness of at least 0.1 nm, preferably at least 10 nm, and most preferably at least 30 nm. As the same time, the thickness is preferably no more than about 2 μm, preferably no more than about 1 μm, and most preferably no more than about 200 nm.

### Additional Protective Layers

In addition to the layers described above, further layers can be added for mechanical and chemical protection. The cell can be encapsulated to provide chemical protection. According to a preferred embodiment, transparent polymers, often referred to as transparent thermoplastic resins, are used as the encapsulation material, if such an encapsulation is present. Preferred transparent polymers in this context are silicon rubber and polyethylene vinyl acetate (PVA). A transparent glass sheet may also be added to the front of the solar cell to provide mechanical protection to the front face of the cell. A back protecting material may be added to the back face of the solar cell to provide mechanical protection. Preferred back protecting materials are those having good mechanical properties and weather resistance. The preferred back protection material according to the invention is polyethylene terephthalate with a layer of polyvinyl fluoride. It is preferred for the back protecting material to be present underneath the encapsulation layer (in the event that both a back protection layer and encapsulation are present).

A frame material can be added to the outside of the solar cell to give mechanical support. Frame materials are well known in the art and any frame material considered suitable in the context of the invention may be employed. The preferred frame material according to the invention is aluminum.

### Method of Preparing a Solar Cell

A solar cell may be prepared by applying the contact layer paste and the electroconductive paste of the invention to an antireflection coating, such as silicon nitride, silicon oxide, titanium oxide or aluminum oxide, on the front side of a semiconductor substrate, such as a silicon wafer. A backside electroconductive paste is then applied to the backside of the solar cell to form soldering pads, i.e. SOL 326. An aluminum paste is then applied to the backside of the substrate, overlapping the edges of the soldering pads formed from the backside electroconductive paste, to form the BSF, Toyo.

The contact layer paste and the electroconductive paste may be applied in any manner known in the art and considered suitable in the context of the invention. Examples include, but are not limited to, impregnation, dipping, pouring, dripping on, injection, spraying, knife coating, curtain coating, brushing or printing or a combination of at least two thereof. Preferred printing techniques are ink-jet printing, screen printing, tampon printing, offset printing, relief printing or stencil printing or a combination of at least two thereof. It is preferred according to the invention that the seed layer paste and the electroconductive paste are applied by printing, preferably by screen printing. Specifically, the screens preferably have mesh opening with a diameter of about 40 μm or less (e.g., about 35 μm or less, about 30 μm or less). At the same time, the screens preferably have a mesh opening with a diameter of at least 10 μm.

In a preferred embodiment, the contact layer paste is printed on a surface of the silicon wafer. Followed by drying at 150-300° C. for 20-120 seconds, the electroconductive paste is then printed over the dried contact layer. The coated wafer is then dried at 150-300° C. for duration 20-120 seconds.

The substrate is then subjected to one or more thermal treatment steps, such as, for example, conventional over drying, infrared or ultraviolet curing, and/or firing. In one embodiment the substrate may be fired according to an appropriate profile. Firing sinters the printed contact layer paste and electroconductive paste so as to form contact layer and solid electrodes respectively. Firing is well known in the art and can be effected in any manner considered suitable in the context of the invention. It is preferred that firing be carried out above the T_{g} of the glass frit materials.

According to the invention, the maximum temperature set for firing is below about 900° C., preferably below about 860° C. Firing temperatures as low as about 800° C. have been employed for obtaining solar cells. Firing temperatures should also allow for effective sintering of the metallic particles to be achieved. The firing temperature profile is typically set so as to enable the burnout of organic materials from the electroconductive paste composition. The firing step is typically carried out in air or in an oxygen-containing atmosphere in a belt furnace. It is preferred for firing to be carried out in a fast firing process with a total firing time of at least 30 seconds, and preferably at least 40 seconds. At the same time, the firing time is preferably no more than about 3 minutes, more preferably no more than about 2 minutes, and most preferably no more than about 1 minute. The time above 600° C. is most preferably in a range from about 3 to 7 seconds. The substrate may reach a peak temperature in the range of about 700 to 900° C. for a period of about 1 to 5 seconds. The firing may also be conducted at high transport rates, for example, about 100-700 cm/min, with resulting hold-up times of about 0.5 to 3 minutes. Multiple temperature zones, for example 3-12 zones, can be used to control the desired thermal profile.

Firing of the seed layer paste and the electroconductive paste on the front and back faces can be carried out simultaneously or sequentially. Simultaneous firing is appropriate if the electroconductive pastes applied to both faces have similar, preferably identical, optimum firing conditions. Where appropriate, it is preferred for firing to be carried out simultaneously. Where firing is carried out sequentially, it is preferable for the back electroconductive paste to be applied and fired first, followed by application and firing of the electroconductive paste to the front face of the substrate.

### Measuring Properties of Solar Cell

The electrical performance of a solar cell is measured using a commercial IV-tester “cetisPV-CTL1” from Halm Elektronik GmbH. All parts of the measurement equipment as well as the solar cell to be tested are maintained at 25° C. during electrical measurement. This temperature should be measured simultaneously on the cell surface during the actual measurement by a temperature probe. The Xe Arc lamp simulates the sunlight with a known AM1.5 intensity of 1000 W/m² on the cell surface. To bring the simulator to this intensity, the lamp is flashed several times within a short period of time until it reaches a stable level monitored by the “PVCTControl 4.313.0” software of the IV-tester. The Halm IV tester uses a multi-point contact method to measure current (I) and voltage (V) to determine the solar cell's IV-curve. To do so, the solar cell is placed between the multi-point contact probes in such a way that the probe fingers are in contact with the bus bars (i.e., printed lines) of the solar cell. The numbers of contact probe lines are adjusted to the number of bus bars on the cell surface. All electrical values were determined directly from this curve automatically by the implemented software package. As a reference standard, a calibrated solar cell from ISE Freiburg consisting of the same area dimensions, same wafer material, and processed using the same front side layout, was tested and the data was compared to the certificated values. At least five wafers processed in the very same way were measured and the data was interpreted by calculating the average of each value. The software PVCTControl 4.313.0 provided values for efficiency.

The invention will now be described in conjunction with the following, non-limiting examples.

### EXAMPLE 1

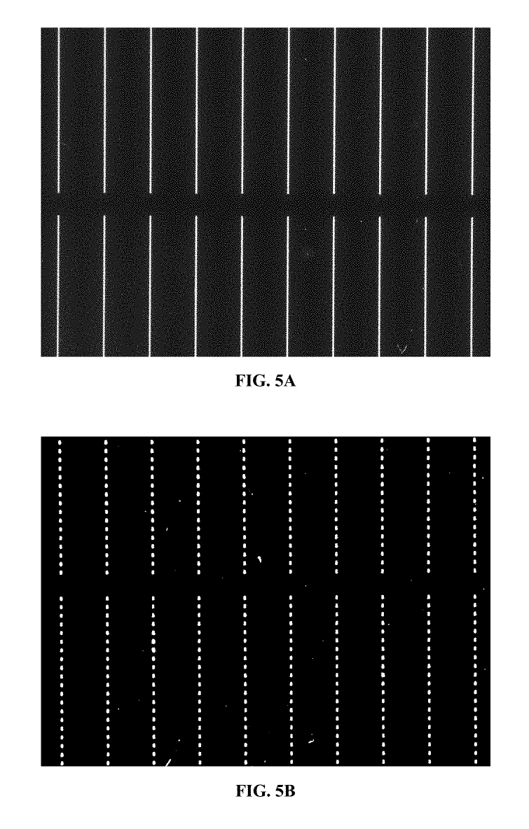

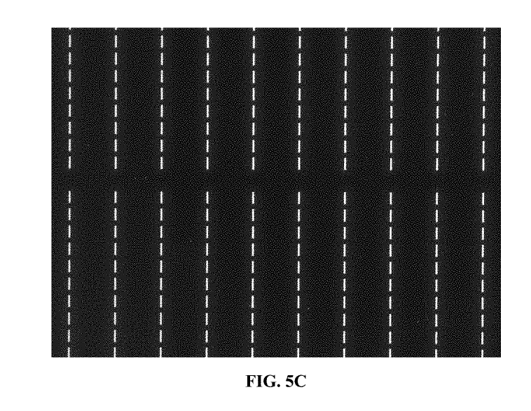

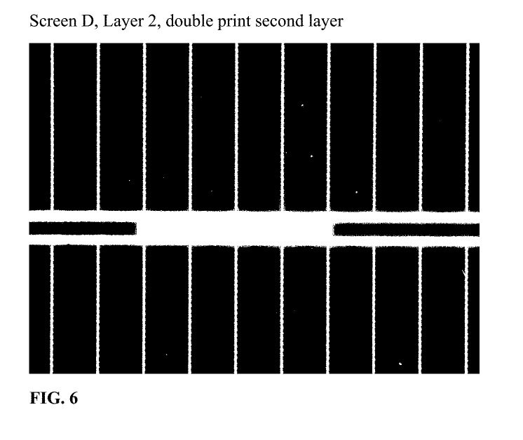

In the experiments summarized in Table 1 below, “Standard” and “Inventive” refer to the patterns for the contact layer paste and electroconductive layer paste as shown in FIGS. 5 and 6.

TABLE 1

| | Double Print (Pastes 1 and 3) | | | Double Print (Pastes 2 and 3) | | |
|---|---|---|---|---|---|---|
| | Standard | Inventive | | Standard | Inventive | |
| Contact Paste Layer 1 | Paste 1 | Paste 1 | Paste 1 | Paste 2 | Paste 2 | Paste 2 |
| Pattern of Contact | A | C | B | A | C | B |
| Paste Layer 1 | | | | | | |
| Electroconductive | Paste 3 | Paste 3 | Paste 3 | Paste 3 | Paste 3 | Paste 3 |
| Paste Layer 2 | | | | | | |
| Pattern of | D | D | D | D | D | D |
| ElectroconductivePaste | | | | | | |
| Layer 2 | | | | | | |
| Area(L1)/Area(L2) | 3/3 | 2/3 | 1/3 | 3/3 | 2/3 | 1/3 |
| Ratio* | 100% | 70% | 40% | 100% | 70% | 40% |
| Eta (%) | 20.04 | 20.06 | 19.69 | 20.05 | 20.04 | 19.82 |
| Voc (v) | 0.650 | 0.653 | 0.652 | 0.650 | 0.652 | 0.653 |

*After printing, areas covered by each corresponding paste increase slightly reative to screen design, because lines expand slightly in printing.

It is clear that Voc is improved in the inventive examples while efficiency remains constant.

The composition of the contact layer paste is shown below:

Paste

| | Paste 1 | Paste 2 |
|---|---|---|
| Silver | 89.5 | 89.5 |
| Glass 1 | 2.58 | |
| Glass 2 | | 2.58 |
| Vehicle | 8.8 | 8.8 |
| Solid % | 91.2% | 91.2% |

Glass 1: Pb—Te—Bi
Glass 2: Pb—Te—Li

The composition of the electroconductive layer paste 3 is shown below:

| Paste 3 | Wt % |
|---|---|
| Silver | 90 |
| Glass | 0.14 |
| Vehicles | 9.86 |
| Total | 100 |

Glass: Bi—Si-Alkali

Eta and additional electrical performance parameters are shown below.

| | Eta | | Isc | | Voc | | FF | |
|---|---|---|---|---|---|---|---|---|
| Ratio | Pastes | Pastes | Pastes | Pastes | Pastes | Pastes | Pastes | Pastes |
| (L1/ | 1 and | 2 and | 1 and | 2 and | 1 and | 2 and | 1 and | 2 and |
| L2) | 3 | 3 | 3 | 3 | 3 | 3 | 3 | 3 |
| 100% | 20.04 | 20.05 | 9.4505 | 9.4761 | 0.6508 | 0.6505 | 79.57 | 79.48 |
| 70% | 20.06 | 20.04 | 9.4407 | 9.4402 | 0.6536 | 0.6523 | 79.40 | 79.48 |
| 40% | 19.69 | 19.82 | 9.3726 | 9.3837 | 0.6530 | 0.6530 | 78.61 | 78.99 |

### EXAMPLE 2

Solar cells prepared with a seed layer paste and an electroconductive layer paste can be formulated as in Table 2 below.

TABLE 2

| | Seed Paste 4 (wt %) | | | Seed Paste 5 (wt %) | | |
|---|---|---|---|---|---|---|
| Contact Paste | Ag 10 wt %/ | | | Ag 10 wt %/ | | |
| Layer 1 | Glass 10 wt % | | | Glass 20 wt % | | |
| Pattern of Contact | A | C | B | A | C | B |
| Paste Layer 1 | | | | | | |
| Electroconductive | Paste 3 | | | | | |
| Paste Layer 2 | | | | | | |
| Pattern of | D | | | | | |
| Electroconductive | | | | | | |
| Paste Layer 2 | | | | | | |
| Area(L1)/Area(L2) | 3/3 | 2/3 | 1/3 | 3/3 | 2/3 | 1/3 |
| Ratio* | 100% | 70% | 40% | 100% | 70% | 40% |

*After printing, areas covered by each corresponding paste increase slightly relative to screen design, because lines expand slightly in printing.

These and other advantages of the invention will be apparent to those skilled in the art from the foregoing specification. Accordingly, it will be recognized by those skilled in the art that changes or modifications may be made to the above described embodiments without departing from the broad inventive concepts of the invention. Specific dimensions of any particular embodiment are described for illustration purposes only. It should therefore be understood that this invention is not limited to the particular embodiments described herein, but is intended to include all changes and modifications that are within the scope and spirit of the invention.

1. A method of preparing a metallization structure on a solar cell, comprising the steps of:
patterning a first composition on a surface of a semiconductor substrate;
applying a second composition over the first composition on the surface of the semiconductor substrate, wherein an area covered by the first composition is 5-95%, preferably 20-95%, more preferably 35-90%, of an area covered by the second composition; and
firing the semiconductor substrate bearing the first composition and the second composition.

2. The method of claim 1, wherein the patterning comprising applying the first composition to the surface of a silicon wafer to form a seed layer, wherein the first composition comprising
i. a silver particle;
ii. at least one glass frit; and
iii. an organic vehicle.

3. The method of claim 2, wherein the second composition is applied on top of the seed layer prepared from the first composition, wherein the second composition comprising
i. a silver particle;
ii. at least one glass frit; and
iii. an organic vehicle.

4. The method of claim 1, wherein the first composition and the second composition are the same, and comprise:
i. a silver particle;
ii. at least one glass frit; and
iii. an organic vehicle.

5. The method of claim 2, wherein the patterning comprising copper plating, metal wire soldering, or conductive oxide sputtering.

6. A metallization structure on a solar cell, comprising before firing:
a contact layer comprising a first composition on a surface of a semiconductor substrate; and
an electroconductive layer comprising a second composition over the first composition on the surface of the semiconductor substrate, wherein an area covered by the contact layer is 5-95%, preferably 20-95%, more preferably 35-90%, of an area covered by the electroconductive layer.
